(19) United States
(12) Patent Application Publication
(10) Pub. No.: US 2009/0010296 A1
(43) Pub. Date: Jan. 8, 2009

(54) Optical transceiver module and method for manufacturing same

(75) Inventors: Yasuhei Shimada, Kanagawa (JP); Shigeru Moribayashi, Kanagawa (JP); Takao Yamazaki, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignees: NEC ELECTRONICS CORPORATION, Kawasaki (JP); NEC CORPORATION, Tokyo (JP)

(21) Appl. No.: 11/979,695

(22) Filed: Nov. 7, 2007

(30) Foreign Application Priority Data
Nov. 9, 2006 (JP) 2006-304266

(51) Int. Cl. H01S 5/026; B29D 11/00

(52) U.S. Cl. 372/50.23; 264/1.1

(57) ABSTRACT

An optical transceiver module and a method for manufacturing thereof, which are adopted for providing a reduced manufacturing cost and an improved signal quality, are achieved. The optical transceiver module 1 includes a VCSEL 13 that is capable of emitting light; a thermoplastic resin layer 22 provided on the VCSEL 13 and transparent to the above-described light; a copper foil 21, provided in the thermoplastic resin layer 22 and the resin layer, and having an opening 21a that is transparent to light; a dimple 22a, provided in a surface of the thermoplastic resin layer 22 in a side opposite to the VCSEL 13; and a lens provided in the dimple. The dimple 22a is located above the opening 21a.

This application is based on Japanese patent application No. 2006-304,266, the content of which is incorporated hereinto by reference.

### BACKGROUND

1. Technical Field

The present invention relates to an optical transceiver module and a method for manufacturing thereof.

2. Related Art

Optical transceivers were expensive modules for uses in backbone transmissions, which have been mounted in conventional communication equipments that have provided transmissions of signal of several Gbps to several tens of Gbps over the distance of around 10 km through optical fibers. As the semiconductor technology is advanced, large scale integrated circuits (LSI) that can be operated at faster rate of about 10 Gbps are popular in the industry, which, in turn, create circumstances where deteriorations in properties of an electric transmission path of about several tens meter between devices or an electric transmission path of several meters in an interior of an apparatus are not negligible. Therefore, better properties in operations at higher frequency of GHz-band are required for printed circuit boards, connectors and cables employed in devices, and thus expensive components should be employed.

A formation of a transmission path on a printed circuit board for assuring a signal band of 10 GHz requires a consideration of a loss due to a skin effect, an inhibition to a transmission loss due to a loss of a dielectric material and an impedance matching over broader bands, an expensive polyimide substrate is generally employed instead of a FR4 glass epoxy group board. Further, an impedance matching requires a formation of a micro strip line, which further requires a formation of a pair of a signal layer with a ground layer, and such signal lines for faster transmission should be formed to have a larger spacing between signal lines, in order to prevent a generation of cross talk. Moreover, an use of an interconnect section composing a plurality of interconnects having a constant length for the purpose of harmonizing propagation delay time for a plurality of signals causes an increase in dimension and requires a multiple-layered structure, thereby increasing a cost for manufacturing printed circuit boards.

Since a design of such signal lines for faster transmission requires conducting a pattern design via a simulation of a transmission, and then conducting a design validation through an evaluation of transmission characteristics of an experimentally manufactured substrate, longer development term and more manpower for design and evaluation are demanded for such design, thereby increasing a cost for such development.

A philosophy for employing an optical fiber having lower loss in broad band for utilizing signal at higher frequency of several GHz or higher become a common approach in recent years, even in applications of transmissions for shorter distances between devices or within a device. For achieving such philosophy, an optical transceiver module, which is capable of being mounted to a small package similar as a LSI package, of being produced in a large production scale and of being inserted in and plugged off with smaller dimension similarly as in an electrical connector is demanded.

Installs of a conventional optical element (laser diode, photo diode or the like), a driver IC for driving thereof and a photocurrent-voltage conversion IC requires an use of a bare chip-mounting to enable an impedance matching for the transmission path, instead of using a conventional wire bonding that exhibit poor high-frequency properties. Further, it is necessary to achieve a convergence of a light flux with an optical lens, in order to provide a coupling of an optical element with an optical fiber with lower loss. Therefore, accuracies in alignments for an optical fiber, an optical lens and an optical element should be adjusted at higher accuracy of around several microns, and such alignments should be achieved at lower cost and in shorter time.

FIG. 7 is a cross-sectional view, illustrating an optical transceiver module disclosed in Japanese Patent Laid-Open No. H9-307144 (1995). An optical lens 101 is formed of radioactive rays response resin directly above a photo emitting surface 205 of a light emitter 103, and an optical axis is adjusted between a light emitter 103 and an optical fiber 104. An upper electrode 503 and a lower electrode 504 are formed on an upper surface and a lower surface of the light emitter 103, respectively. Leads 505 are connected to each of the upper electrode 503 and the lower electrode 504.

The optical lens 101 is formed by the following procedure. First of all, a resist layer composed of a radioactive response resin is formed on the light emitter 103, and then a section directly above the photo emitting surface 205 is covered with a mask. Subsequently, portions of the resist layer in other sections are removed. Thereafter, the remained portions of the resist layer are formed in a hemisphere-shape to obtain the optical lens 101.

In addition to above, prior art literatures related to the present invention also include Japanese Patent Laid-Open No. 2006-140382 and Japanese Patent Laid-Open No. S58-186977, in addition to the above-described Japanese Patent Laid-Open No. H9-307144.

The technology disclosed in Japanese Patent Laid-Open No. H9-307144 does not involve any discussion related to a transmission path for transmitting an electrical signal that is received by or transmitted by an optical element, and, thus in the conventional technology, such transmission path is often generally formed by employing bonding wires that are generally used in typical semiconductor producing processes.

However, when an electrical signal at a frequency of several GHz or higher is transmitted, a nature of an wire section of such bonding wire behaving as an inductance cannot be ignored, and thus a reflection by the transmission path due to an unconformity in the impedance may cause a deterioration in signal quality.

To solve the problem, it is essential that an optical element, an IC for driving thereof and an IC for photocurrent-voltage conversion are flip-chip mounted by employing a micro strip line and a strip line for the signal transmission path, thereby achieving a transmission of a signal with higher quality even in a case of utilizing a signal at higher rate of several tens Gbps or higher.

However, in general, the light-receiving surface or the light-emitting surface of the optical element are simultaneously formed via a process for manufacturing semiconductor devices on a wafer, thereby providing spatial relationship of the photo acceptance surface or the light-emitting surface to be included in a signal pad of the semiconductor device. Therefore, when a signal layer of the above-described micro strip line or the strip line is connected thereto, the light-receiving surface or the light-emitting surface of the optical element is pushed to a signal layer, so that the optical element protrudes from the surface of the wafer, resulting in being in contact with the signal layer. In such circumstances, lens can not be formed on the optical element unlike the conventional technology, and therefore, alignments of the optical element, the lens and the optical fiber should be carried out twice as different components.

### SUMMARY

According to one aspect of the present invention, there is provided an optical transceiver module, comprising: an optical element receives or emits light;

a resin layer formed above said optical element, and transmits said light; a conductive layer formed in said resin layer, and has an opening transmits said light; a dimple presented in the opposite side of said optical element in said resin layer; and a lens formed in said dimple, wherein said dimple is located above said opening.

The optical transceiver module of the present invention is provided with the copper foil in the resin layer, and thus the copper foil may be employed as a transmission path such as a strip line or a micro strip line. This achieves providing a transmission medium having higher signal quality. Further, the lens is provided in the dimple of the resin layer located above the opening the copper foil. Such structure allows forming the lens via a self-alignment manner, eliminating a need for an alignment process with higher precision. This contributes to a reduction in a manufacturing cost for optical transceiver modules.

According to another aspect of the present invention, there is provided a method for manufacturing the above-described optical transceiver module, comprising: preparing the resin layer that includes the copper foil; and dropping a liquid resin in the dimple of the resin layer to form the lens.

In the manufacturing method, the lens is formed by dropping the resin in the above-described dimple. This allows forming the lens via a self-alignment manner, thereby eliminating a need for an alignment process with higher precision.

According to the present invention, the optical transceiver module and method for manufacturing thereof, which are adopted for providing a reduced manufacturing cost and an improved signal quality, are achieved.

The above and other objects, advantages and features of the present invention will be more apparent from the following description of certain preferred embodiments taken in conjunction with the accompanying drawings, in which:

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view, illustrating an embodiment of an optical transceiver module according to the present invention;

FIG. 2 is a cross-sectional view, illustrating a portion of the optical transceiver module of FIG. 1;

FIG. 3 is a plan view, illustrating the FPC from the upper view point;

FIG. 4 is a cross-sectional view, useful in describing an embodiment of a method for manufacturing an optical transceiver module according to the present invention;

FIG. 5 is a cross-sectional view, useful in describing an embodiment of a method for manufacturing an optical transceiver module according to the present invention;

FIG. 6 is a cross-sectional view, useful in describing an embodiment of a method for manufacturing of optical transceiver module according to the present invention; and

FIG. 7 is a cross-sectional view, illustrating a conventional optical transceiver module.

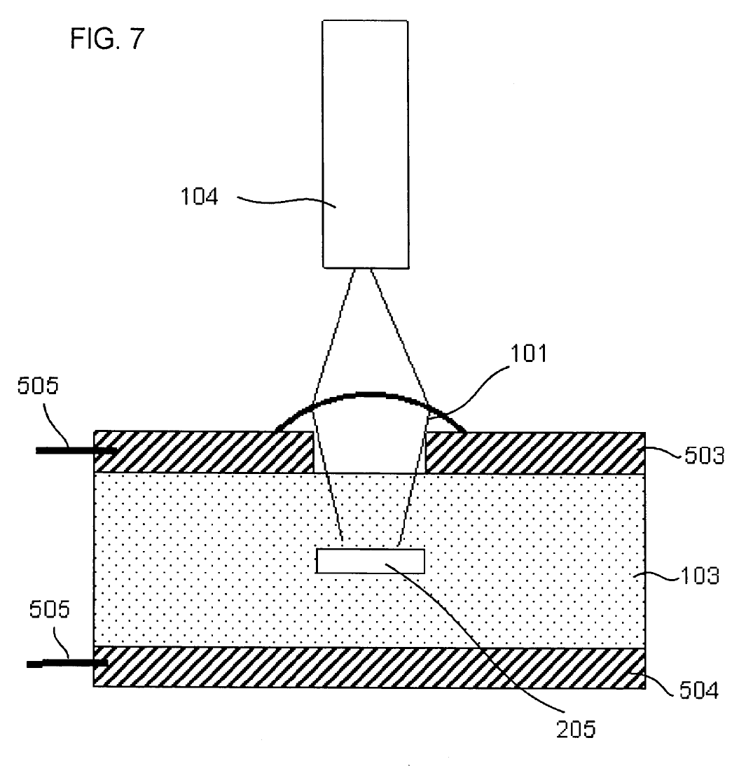

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable exemplary implementations of optical transceiver modules and methods for manufacturing thereof according to the present invention will be described in reference to the annexed figures. In all figures, identical numeral is assigned to an element commonly appeared in the description of the present invention in reference to the figures, and the detailed description thereof will not be repeated.

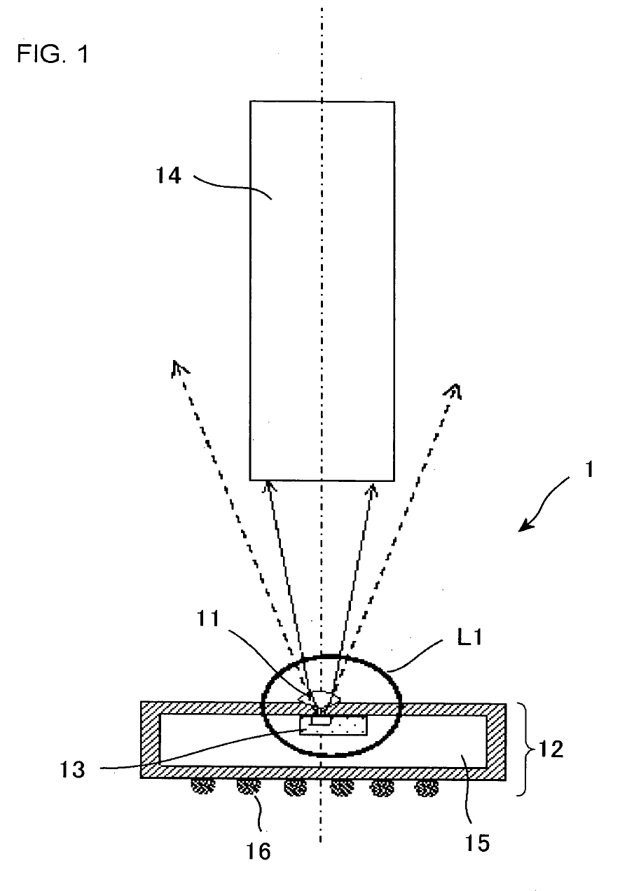

FIG. 1 is a cross-sectional view, illustrating an embodiment of an optical transceiver module according to the present invention. An optical-transceiver module 1 includes a vertical cavity surface emitting laser (VCSEL) 13 serving as an optical element. Such VCSEL 13 is provided in a flexible carrier folded real chip size package (FFCSP), together with a metallic support 15. Light flux emitted from the VCSEL 13 is entered in an optical fiber 14 via a lens 11 formed on the FFCSP 12. By employing such lens 11, the light flux, which is spread as shown by the dotted line, is focused as shown by the solid line to reduce a coupling loss, so that a coupling to the optical fiber 14 with an improved efficiency can be achieved.

Further, an electric power and signals are supplied to the VCSEL 13 via terminals 16 located on the back surface of the FFCSP 12. An electrical signal that drives the VCSEL 13 is transmitted from a driving IC mounted on the FFCSP 12 (not shown) to the VCSEL 13 through the copper foil 21 as will be discussed later.

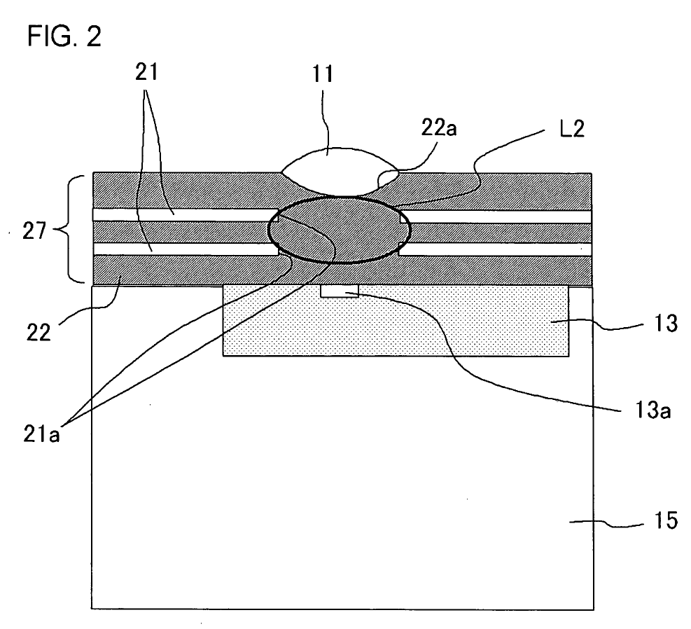

FIG. 2 is a cross-sectional view, illustrating a portion of the optical transceiver module 1 (section surrounded by line L1 of FIG. 1). The thermoplastic resin layers 22 that are transparent to a light from the VCSEL 13 are provided on the VCSEL 13. Copper foils 21 are provided between the thermoplastic resin layers 22. The copper foil 21 is composed of a plurality of layers (two layers in the present embodiment). The copper foil 21 is used as a transmission path of an electrical signal that is to be received by the VCSEL 13. Such copper foil 21 may preferably composes a strip line or a micro strip line. An opening 21a that is transparent to light from the VCSEL 13 is formed in a section located above the emitting section 13a of the VCSEL 13 (section surrounded with line L2) in the copper foil 21. The copper foils 21 and the thermoplastic resin layers 22 constitute a flexible printed circuits (FPC) 27. More specifically, the FPC 27 has a structure constituted of the copper foils 21 and the thermoplastic resin layers 22 that are alternately stacked.

The upper surface of the thermoplastic resin layer 22 (surface in the side opposing to the VCSEL 13) is provided with a dimple 22a. The dimple 22a is located above the opening 21a of the copper foil 21. The bottom surface of the dimple 22a have a curved-shape. The maximum depth of the dimple 22a is substantially equivalent to the depth of the opening 21a. Here, the depth of the opening 21a is equivalent to the thickness of the copper foil 21, and when the copper foil 21 is composed of a plurality of layers, the depth of the opening is equivalent to the grand total of thickness of those copper foils 21. Therefore, in the configuration illustrated in the present embodiment, the maximum depth of the dimple 22a is substantially equivalent to the thickness of two pieces of copper foil 21.

The lens 11 is formed in the dimple 22a. The lens 11 is formed by a high refractive index resin, which has higher refractive index than polyimide resin. In accordance with the curved bottom surface of the dimple 22a, the geometry of the lower surface of the lens 11 (surface of dimple 22a side) is convex. In the present embodiment, the upper surface of the lens 11 (surface opposite to the side of the dimple 22a) is also convex. More specifically, the lens 11 is a double convex lens.

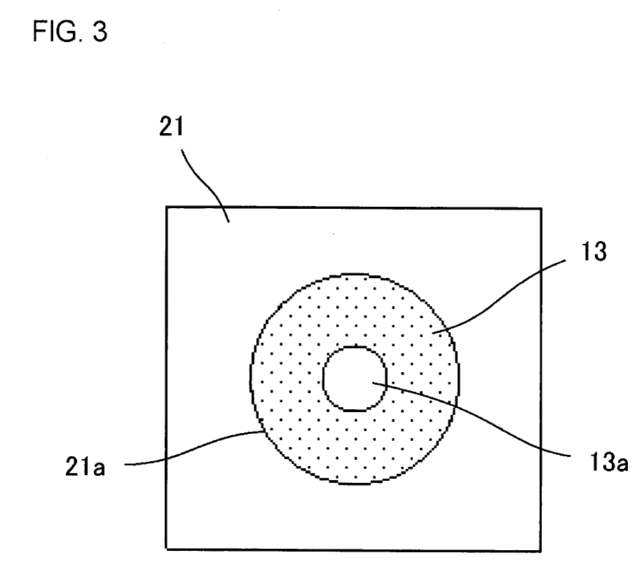

FIG. 3 is a plan view, illustrating the FPC 27 from the upper view point. The diagram shows a condition before the lens 11 is formed. As shown in FIG. 3, the emitting section 13a can be visible through the opening 21a formed in the copper foil 21.

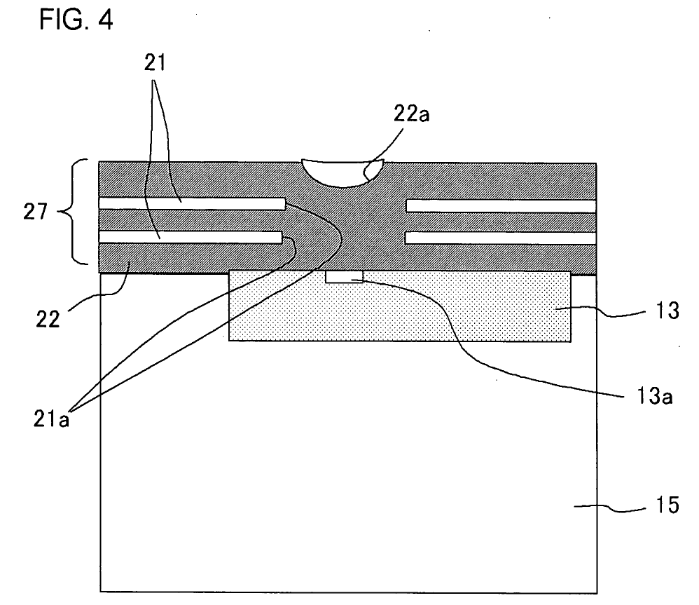

In reference to FIG. 4 to FIG. 6, an example of a method for manufacturing the optical transceiver module 1 will be described as an exemplary implementation of methods for manufacturing the optical transceiver module according to the present invention. The manufacturing method includes: preparing the thermoplastic resin layers 22 and the copper foils 21; and dropping a liquid resin into the dimple 22a in the thermoplastic resin layer 22 to form the lens 11.

In the operation of preparing the thermoplastic resin layer 22, the thermoplastic resin layers 22 and the copper foils 21 are alternately stacked. At this time, right after the copper foil 21 for each layer is formed, the formed copper foil 21 is patterned to form the opening 21a. This allows natural formation of the dimple 22a above the opening 21a (FIG. 4).

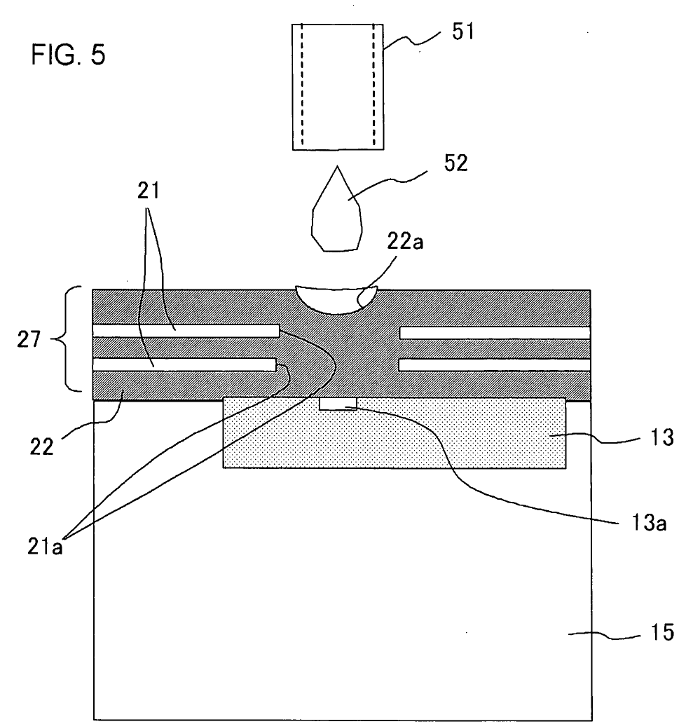

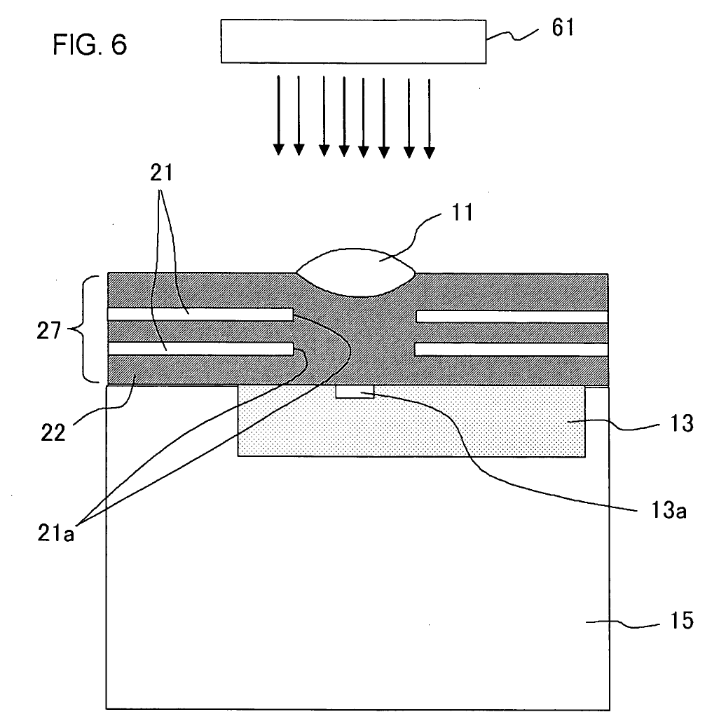

In the operation of forming the lens 11, a liquid UV-cure resin 52 is dropped to the inside of the dimple 22a from a dispenser probe 51 (FIG. 5). The UV-cure resin 52 is a high refractive index resin, which has higher refractive index than polyimide resin. Thereafter, ultra-violet ray is applied to the UV-cure resin 52 within the dimple 22a by employing an UV light source 61. This provides a formation of the lens 11 (FIG. 6).

Advantageous effects obtained by the configuration of the present embodiment will be described. The copper foil 21 is provided in the thermoplastic resin layer 22 in the optical transceiver module 1, and therefore the copper foil 21 may be employed as a transmission path such as a strip line or a micro strip line. This achieves providing a transmission medium having higher signal quality. Thus, the optical module that can be operated at faster rate of several tens Gbps can be achieved. Further, the lens 11 is provided within the dimple 22a in the thermoplastic resin layer 22 located above the opening 21a of the copper foil 21. Such structure allows forming the lens 11 via a self-alignment manner. Actually, the lens 11 is formed via a self-alignment manner in the above-described manufacturing process by dropping the UV-cure resin 52 into the dimple 22a. This contributes to a reduction in a manufacturing cost for the optical transceiver module 1.

In the design of the optics coupling, the design of the lens and the accuracy in the alignment during the assembly process are generally critical. In the present embodiment, the dimple 22a is provided in the FFCSP 12 having the VCSEL 13 mounted thereon, so that only necessary number of lens 11 can be formed in one process with higher positional accuracy. In addition, since the lens 11 is formed by utilizing the dimple 22a of the thermoplastic resin layer 22, a need for employing an expensive metal mold can be eliminated. Further, since the lens 11 is aligned with the VCSEL 13 via a self-alignment manner with higher accuracy, need for employing a cost-consuming aligning process can be eliminated.

While the alignment of the VCSEL 13 with the FPC27 is necessary for providing an electric coupling, it is sufficient to conduct a process of heating a stage to soften the thermoplastic resin layer 22, and a pressure is applied thereto, and then cooling off to an ambient temperature. Therefore, since time required for applying an adhesive agent or for curing the adhesive agent is not necessary unlike conventional methods, the benefit of eliminating a need for a fixture is achieved, thereby being adopted for mass productions.

Since the lens 11 is double convex lens, a reduced focal distance can be achieved, as compared with lens having convex plane only in one side. This achieves a reduced distance from the optical fiber 14, thereby contributing a miniaturization of devices.

As described above, since the lens can be constituted with self alignment while the electricity transmission path having better high frequency property is coupled according to the present embodiment, smaller optical transceivers, which are adopted for mass productions, can be constituted at lower cost.

The optical transceiver module and method for manufacturing thereof according to the present invention is not limited to the above-described embodiment, and various modifications are also available. While the above-described embodiment illustrates the light-emitting optical transceiver module, the optical transceiver module of the present invention may also be light-receiving optical transceiver module. In such case, a light-receiving element such as a photo diode may be employed, instead of employing the VCSEL 13.

Further, while the UV-cure resin 52 (see FIG. 5) is exemplified in the above-described embodiment, a thermosetting resin may alternatively be employed, instead of employing the UV-cure resin 52. In such case, the thermosetting resin in the dimple 22a can be heated to be cured, thereby forming the lens 11.

What is claimed is:

1. An optical transceiver module, comprising:
an optical element receives or emits light;
a resin layer formed above said optical element, and transmits said light;
a conductive layer formed in said resin layer, and has an opening transmits said light;
a dimple presented in the opposite side of said optical element in said resin layer; and
a lens formed in said dimple, wherein said dimple is located above said opening.

2. The optical transceiver module according to claim 1,
wherein said bottom surface of said dimple has a curved surface, and said surface of the side of said dimple has a convex shape.

3. The optical transceiver module according to claim 1,
wherein a surface of the opposite side of said dimple of said lens has a convex shape.

4. The optical transceiver module according to claim 1,
wherein said lens is formed by a high refractive index resin has a higher refractive index than polyimide resin.

5. The optical transceiver module according to claim 1,
wherein maximum depth of said dimple is substantially equivalent to a depth of said opening.

6. The optical transceiver module according to claim 1,
wherein said conductive layer is used as a transmission path of electrical signal received or transmitted by said optical element.

7. The optical transceiver module as according to claim 6,
wherein said conductive layer makes up a strip line or a micro strip line.

8. The optical transceiver module as according to claim 7,
wherein said conductive layer is a copper foil.

9. A method for manufacturing the optical transceiver module, comprising:
preparing a resin layer has a dimple on the surface; and
forming said lens by dropping a liquid resin in said dimple of said resin layer.

10. The method for manufacturing the optical transceiver module according to claim 9,
wherein said liquid resin has a higher refractive index than polyimide resin.
